(19) United States
(12) Patent Application Publication
(10) Pub. No.: US 2015/0050478 A1
(43) Pub. Date: Feb. 19, 2015

(54) GAS BARRIER FILM AND MANUFACTURING METHOD OF GAS BARRIER FILM

(71) Applicant: FUJIFILM Corporation, Tokyo (JP)

(72) Inventors: Yoshihiko MOCHIZUKI, Kanagawa (JP); Jun FUJINAWA, Kanagawa (JP)

(73) Assignee: FUJIFILM CORPORATION, Tokyo (JP)

(21) Appl. No.: 14/498,228

(22) Filed: Sep. 26, 2014

Related U.S. Application Data
(63) Continuation of application No. PCT/JP2013/053977, filed on Feb. 19, 2013.

(30) Foreign Application Priority Data
Mar. 29, 2012 (JP) 2012-077767

(51) Int. Cl. C23C 16/34; C23C 16/50

(52) U.S. Cl. CPC C23C 16/345; C23C 16/50
USPC 428/216; 427/579

(57) ABSTRACT

A gas barrier film including a substrate of which the surface is formed of an organic material; an inorganic film which is formed on the substrate and contains silicon nitride; and a mixed layer which is formed in an interface between the substrate and the inorganic film, and contains components derived from the organic material and the inorganic film, wherein a compositional ratio N/Si between nitrogen and silicon contained in the inorganic film is 1.00 to 1.35, the inorganic film has a film density of 2.1 g/cm³ to 2.4 g/cm³ and a film thickness of 10 nm to 60 nm, and the mixed layer has a thickness of 5 nm to 40 nm.

### CROSS-REFERENCE TO RELATED APPLICATIONS

This application is a Continuation of PCT International Application No. PCT/JP2013/053977 filed on Feb. 19, 2013, which claims priority under 35 U.S.C. §119(a) to Japanese Application No. 2012-077767 filed on Mar. 29, 2012. Each of the above application(s) is hereby expressly incorporated by reference, in its entirety, into the present application.

### BACKGROUND OF THE INVENTION

The present invention relates to a gas barrier film used for a display and the like and to a manufacturing method of the gas barrier film. Specifically, the present invention relates to a gas barrier film, which is excellent not only in gas barrier properties but also in transparency and flexibility, and to a manufacturing method of the gas barrier film.

A gas barrier film (moisture vapor barrier film) is formed at sites required to exhibit moisture-proof properties in various apparatuses including an optical device, a display apparatus such as a liquid crystal display or an organic EL display, a semiconductor apparatus, and a thin-film solar cell, or formed in packing materials used for packing parts, foods, clothing, electronic parts, and the like. Moreover, a gas barrier film obtained by using a resin film or the like as a base material (substrate) and forming a gas barrier film thereon is also used for the above purposes.

As the gas barrier film, films formed of various materials such as silicon oxide, silicon oxynitride, and aluminum oxide are known. As one of the gas barrier films, a gas barrier film containing silicon nitride as a main component is known.

For the gas barrier films, not only excellent gas barrier properties, but also various characteristics such as high degree of light transmission properties (transparency) and a high degree of oxidation resistance are required according to the purpose of use.

In order to fulfil the requirements, regarding the gas barrier film formed of silicon nitride, various measures are being suggested.

For example, JP 2011-63851 A (Patent document 1) describes a gas barrier film (silicon nitride film) in which a compositional ratio of N/Si is 1 to 1.4; a hydrogen content is 10 at % to 30 at %; and in a Fourier-transform infrared absorption spectrum, an absorption peak resulting from the stretching vibration of Si—H is positioned within a range from 2,170 cm⁻¹ to 2,200 cm⁻¹; and an intensity ratio [I(Si—H)/I(Si—N)] between an absorption peak intensity I(Si—H) resulting from the stretching vibration of Si—H and an absorption peak intensity I(Si—N) resulting from the stretching vibration of Si—N in the vicinity of 840 cm⁻¹ is 0.03 to 0.15.

Having such characteristics, the gas barrier film can be excellent not only in gas barrier properties but also in oxidation resistance, transparency, and flexibility.

JP 2011-136570 A (Patent document 2) describes a transparent gas barrier film having a gas barrier layer, which is constituted with a low-density layer, a high density layer, and a medium-density layer formed between the low-density layer and the high-density layer, on a substrate.

Having such characteristics, the transparent gas barrier film can be excellent not only in adhesiveness but also in transparency and gas barrier resistance.

JP 11-350140 A (Patent document 3) describes a method in which a mixed layer consisting of a carbon nitride film and a base material is formed by applying a high bias voltage in the form of a negative pulse to the base material, and accelerating ions in plasma with high energy to introduce the ions into the base material, and then, a carbon nitride film is formed on the mixed layer.

The document describes that according to the manufacturing method of a carbon nitride film, due to the mixed layer, a carbon nitride film exhibiting a high degree of adhesiveness can be obtained.

JP 2003-305802 A (Patent document 4) describes a barrier film in which a resin layer has been formed between a base material and a barrier layer. The document describes that since the barrier film has a resin layer between a base material and a barrier layer, the adhesiveness between the base material and the barrier layer is improved, and the barrier properties are also improved.

JP 2006-68992 A (Patent document 5) describes a gas barrier film in which a stress relaxation layer has been formed between a base material and a gas barrier layer. The document describes that since the gas barrier film has the stress relaxation layer, flexibility is improved, bending resistance is enhanced, and further, interlayer adhesiveness is improved.

### SUMMARY OF THE INVENTION

As described in Patent document 1, in a gas barrier film containing silicon nitride as a main component, if a compositional ratio between silicon and nitrogen, a hydrogen content, an absorption peak intensity resulting from the stretching vibration of Si—H in a Fourier-transform infrared absorption spectrum, and the like are specified, it is possible to obtain a gas barrier film which is excellent not only in gas barrier properties but also in oxidation resistance, transparency, and flexibility.

However, even in the scope of the gas barrier film of Patent document 1, there is a problem in that when the proportion of nitrogen increases, durability or flexibility deteriorates, the gas barrier film is cracked, and thus the gas barrier properties deteriorate. There is also a problem in that when the film density of the gas barrier film is too high or when the film thickness is too great, the flexibility deteriorates.

Patent document 2 describes that since the transparent gas barrier film thereof has a low-density layer, a medium-density layer, and a high-density layer in a gas barrier film containing the same elements, the adhesiveness among the respective layers is improved. However, in the transparent gas barrier film, the adhesiveness between the gas barrier film and an organic film as a base layer of the gas barrier film is not improved, and thus, flexibility or durability is not improved.

Patent document 3 describes that in the manufacturing method of a carbon nitride film, a mixed layer consisting of a carbon nitride film and a base material is formed between a carbon nitride film and a base material, hence the adhesiveness of the carbon nitride film is improved. However, the carbon nitride film is formed in members required to exhibit abrasion resistance, such as bearings of various rotary machines, sliding members such as a slider, and tools. Accordingly, the carbon nitride film is different from a gas barrier film required to exhibit gas barrier properties, and the document does not describe a film containing silicon nitride as a main component. Moreover, since the carbon nitride film is formed in a rigid body as described above, the flexibility of the film is not considered.

Patent document 4 describes a method of improving adhesiveness and barrier properties by forming a resin layer between a base material and a barrier layer. It is relatively easy to improve the interlayer adhesiveness between organic substances (the base material and the resin layer). However, since the barrier layer is an inorganic substance and hard, and exhibits poor reactivity, it is difficult to improve the interlayer adhesiveness between the resin layer and the barrier layer.

Patent document 5 describes a method of improving flexibility and adhesiveness by forming a stress relaxation layer between a base material and a barrier layer. However, in Patent document 5, each of the gas barrier layer and the stress relaxation layer is separately formed into a film. Consequentially, the gas barrier layer and the stress relaxation layer have a clear interface therebetween, and thus, sufficient adhesiveness is not obtained. Furthermore, the document describes a method of improving the adhesiveness between the base material and the gas barrier layer by a physical anchor effect obtained by protrusions which are formed by roughening the surface of the base material. However, the method has a problem in that when a force equal to or stronger than the anchor effect is applied, peeling of the barrier layer occurs.

Objects of the present invention are to solve the above problems in the conventional techniques, and to provide a gas barrier film which exhibits a high degree of gas barrier properties and is excellent in transparency, durability, and flexibility and a manufacturing method of the gas barrier film.

To attain the above objects, the present invention provides a gas barrier film comprising: a substrate of which the surface is formed of an organic material; an inorganic film which is formed on the substrate and contains silicon nitride; and a mixed layer which is formed in an interface between the substrate and the inorganic film, and contains components derived from the organic material and the inorganic film, wherein a compositional ratio N/Si between nitrogen and silicon contained in the inorganic film is 1.00 to 1.35, the inorganic film has a film density of 2.1 g/cm³ to 2.4 g/cm³ and a film thickness of 10 nm to 60 nm, and the mixed layer has a thickness of 5 nm to 40 nm.

Preferably, the gas barrier film further comprises: an organic film formed on the inorganic film; and an inorganic film formed on the organic film.

Preferably, the substrate has a layer in which an organic film and an inorganic film are alternately formed.

The present invention also provides a manufacturing method of the above-mentioned gas barrier film, wherein while a long substrate of which the surface is formed of an organic material is being transported in a longitudinal direction thereof, by using a film forming unit having a pair of electrodes disposed so as to make the substrate being transported interposed therebetween, an inorganic film containing silicon nitride is formed on the substrate by capacitively-coupled plasma CVD, and for forming the inorganic film, plasma excitation power with a high frequency of 10 MHz to 100 MHz is supplied to one of the pair of electrodes, and bias power 0.02 to 0.5 times stronger than the plasma excitation power is supplied to the other electrode at a frequency of 0.1 MHz to 1 MHz which is lower than the frequency of the plasma excitation power.

Preferably, raw material gas for forming the inorganic film contains silane gas and ammonia gas, and a gas flow ratio between the silane gas and the ammonia gas is SiH₄:NH₃=1:1.2 to 1:3.0.

Preferably, a film formation pressure at the time of forming the inorganic film is controlled to be 10 Pa to 80 Pa.

According to the present invention constituted as above, it is possible to obtain a gas barrier film which is excellent not only in gas barrier properties but also in transparency and exhibits a high degree of flexibility and durability, and to obtain a manufacturing method of the gas barrier film.

### BRIEF DESCRIPTION OF THE DRAWINGS

FIG. 1 is a diagram schematically showing an example of the gas barrier film of the present invention.

FIG. 2 is a diagram schematically showing another example of the gas barrier film of the present invention.

FIG. 3 is a diagram schematically showing an example of a film-forming apparatus for performing the manufacturing method of the gas barrier film of the present invention.

### DETAILED DESCRIPTION OF THE INVENTION

Hereinafter, the gas barrier film and the manufacturing method of the gas barrier film of the present invention will be described in detail based on preferable examples shown in the attached drawings.

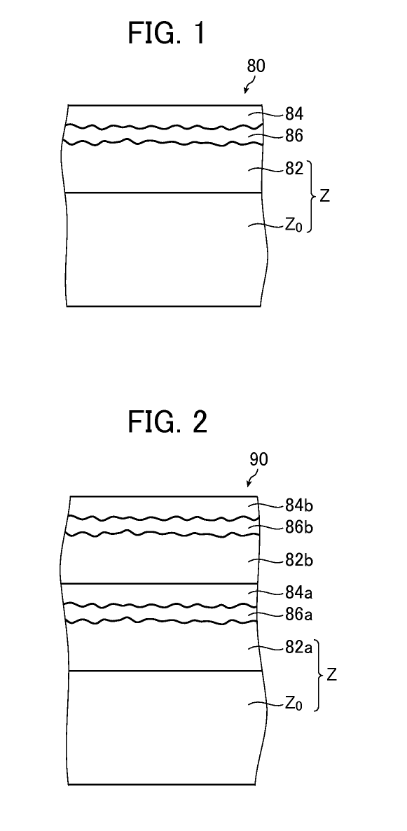

FIG. 1 schematically shows an example of the gas barrier film of the present invention.

In a gas barrier film 80 shown in FIG. 1, on an organic film 82 of a substrate Z in which the organic film 82 has been formed on the surface of a base material Z₀ as a base, an inorganic film 84 as a gas barrier film has been formed. In the interface between the organic film 82 and the inorganic film 84, a mixed layer 86 of an organic material/inorganic material (hereinafter, for convenience, referred to as a “mixed layer 86”), in which the organic material of the organic film 82 and the material of the inorganic film 84 have been mixed with each other, has been formed.

In the manufacturing method of the gas barrier film of the present invention, the surface of the substrate Z (substance to be treated) on which the inorganic film 84 is formed is formed of various organic materials (organic substances) such as polymer materials (polymers) or resin materials.

As the substrate Z, various substances can be used, as long as the surface thereof is formed of an organic material, and an inorganic film can be formed thereon by plasma CVD. Specifically, a substrate Z formed of a polymer material such as polyethylene terephthalate (PET), polyethylene naphthalate, polyethylene, polypropylene, polystyrene, polyamide, polyvinyl chloride, polycarbonate, polyacrylonitrile, polyimide, polyacrylate, or polymethacrylate is one of the preferable examples thereof.

Moreover, in the present invention, as the substrate Z, a film-like substance (sheet-like substance) such as a long film (a web-like film) or a cut sheet-like film is preferable. However, the substrate Z is not limited thereto, and various articles (members) of which the surface is formed of an organic material, such as an optical device like a lens or an optical filter, a photoelectric conversion element like an organic EL or a solar cell, and a display panel like a liquid crystal display or an electronic paper, can be used as the substrate Z.

Furthermore, in the substrate Z, a plastic film (polymer film), an article formed of an organic material, a metal film, a glass plate, an article made of various metals, or the like may be used as a main body (base material Z₀), and on the surface thereof, the organic film (layer) 82 formed of various organic materials for obtaining various functions, such as a protective layer, an adhesive layer, a light reflection layer, a light shielding layer, a planarizing layer, a buffer layer, or a stress relaxation layer, may be formed.

Herein, these functional layers are not limited to a single layer, and a layer formed of a plurality of functional layers may be used as the organic film 82 in the substrate Z.

In the gas barrier film 80 illustrated in the drawing, a substance in which the organic film 82 has been formed on the surface of the base material Z₀ is used as the substrate Z, the inorganic film 84 has been formed thereon, and the mixed layer 86 has been formed in the interface between the organic film 82 and the inorganic film 84.

In the present invention, the gas barrier film 80 has the organic film 82 as a base layer of the inorganic film 84. Accordingly, concavities and convexities present within the surface of the base material Z₀ can be concealed, and the surface for forming the inorganic film 84 can be planarized. Consequentially, excellent characteristics of the inorganic film 84, that is, excellent characteristics of the gas barrier film can be sufficiently demonstrated, and the gas barrier film 80 which is superior not only in gas barrier properties, but also in transparency and durability, and further in flexibility can be obtained.

In the present invention, there is no particular limitation on the material (main component) forming the organic film 82, and various known organic substances (organic compounds) can be used. Particularly, various resins (organic polymer compounds) are preferable examples thereof.

One of the examples includes an epoxy resin, an acrylic resin, a methacrylic resin, polyester, a methacrylic acid-maleic acid copolymer, polystyrene, a transparent fluororesin, polyimide, fluorinated polyimide, polyamide, polyamide-imide, polyetherimide, cellulose acylate, polyurethane, polyether ketone, polycarbonate, fluorene ring-modified polycarbonate, alicyclic ring-modified polycarbonate, fluorene ring-modified polyester, or the like.

There is no particular limitation on a film formation method (formation method) of the organic film 82, and all of known organic film formation methods can be used.

One of the examples thereof includes a coating method in which the base material Z₀ is coated with a coating material, which is prepared by dissolving (dispersing) an organic substance or an organic monomer with a polymerization initiator and the like in a solvent, by known coating means such as roll coating, gravure coating, or spray coating, followed by drying, and the resultant coating film is cured as necessary by heating, UV irradiation, electron beam irradiation, or the like. Moreover, it is also possible to suitably use a flash vapour deposition method in which an organic substance or the same coating material as used in the aforementioned coating method is evaporated to form a vapor-deposited film on the base material Z₀; cooling/condensation is performed on the vapor-deposited film to form a liquid film; and the liquid film is cured by UV or an electron beam to form a film as the organic film 82. Furthermore, it is also possible to use a transfer method in which the organic film 82 having been formed into a sheet shape is transferred onto the base material Z₀.

In the present invention, the thickness of the organic film 82 is not particularly limited, and may be appropriately set according to the surface properties or thickness of the substrate Z, gas barrier properties required, and the like. Herein, the thickness of the organic film 82 is preferably 0.1 μm to 50 μm.

If the thickness of the organic film 82 is within the above range, it is possible to obtain preferable results in that the surface for forming the inorganic film 84 can be suitably planarized by more reliably concealing irregularities present on the surface of the substrate Z, adhesiveness and flexibility can be improved, and a high degree of transparency can be maintained.

In the present invention, the organic film 82 is not limited to a film formed of a single film of an organic substance and may be formed of a plurality of films of organic substances.

For example, on a film of an organic substance formed by the coating method, a film of an organic substance formed by the flash vapor deposition method may be provided, and these two layers of organic films may form the organic film 82.

In the gas barrier film 80, the inorganic film 84 is formed on the organic film 82.

The inorganic film 84 is a gas barrier film and contains silicon nitride as a main component. In this film, a compositional ratio (atomic ratio) of N/Si (nitrogen/silicon) is 1 to 1.35. The inorganic film 84 has a film density of 2.1 g/cm³ to 2.4 g/cm³ and a film thickness of 10 nm to 60 nm.

The mixed layer 86 is formed in the interface between the organic film 82 and the inorganic film 84, and the thickness of the mixed layer 86 is 5 nm to 40 nm.

Herein, the mixed layer 86 is a layer containing a component derived from the organic film 82 and a component derived from the inorganic film 84. Therefore, the position (surface) where there is no component derived from the inorganic film 84 is the interface between the organic film 82 and the mixed layer 86, and the position (surface) where there is no component derived from the organic film 82 is the interface between the inorganic film 84 and the mixed layer 86.

In the gas barrier film 80, the mixed layer 86 containing the components derived from the organic film 82 and the inorganic film 84 has been formed between the organic film 82 and the inorganic film 84, in a state in which there is no clear interface between the organic film 82 and the inorganic film 84.

Having the above constitution, the present invention has realized a gas barrier film which is excellent not only in gas barrier properties but also in transparency (light transmission properties), and further in durability and flexibility.

As described above, as a gas barrier film used for various displays or semiconductor apparatuses, packing materials, and the like, a film containing silicon nitride as a main component is used. According to the purpose of use, not only gas barrier properties but also a high degree of transparency, durability, and flexibility are required for the gas barrier film.

In order to realize a gas barrier film having better characteristics that fulfil such requirements, Patent document 1 suggests a method of specifying not only a compositional ratio between silicon and nitrogen but also a hydrogen content, an absorption peak intensity resulting from the stretching vibration of Si—H in a Fourier-transform infrared absorption spectrum, and the like; Patent document 2 suggests a method of constituting a gas barrier film with a low-density layer, a medium-density layer, and a high-density layer; Patent document 4 suggests a method of forming an organic film between a base material and a gas barrier layer; and Patent document 5 suggests a method of forming a stress relaxation layer between a base material and a gas barrier layer.

However, as described above, even in the scope of the gas barrier film of Patent document 1, there is a problem in that when the proportion of nitrogen increases, durability or flexibility deteriorates, the gas barrier film is cracked, and thus the gas barrier properties deteriorate. There is also a problem in that when the film density of the gas barrier film is too high or when the film thickness is too great, flexibility deteriorates.

Moreover, in the gas barrier film of Patent document 2, the adhesiveness between the gas barrier film and an organic film as a base layer of the gas barrier film is not improved, and thus, flexibility or durability is not improved.

Furthermore, in the barrier film of Patent document 4, the adhesiveness between the organic film and the gas barrier film is insufficient, and in the barrier film of Patent document 5, the adhesiveness between the stress relaxation layer and the gas barrier layer is insufficient.

In contrast, in the present invention, a compositional ratio of N/Si, a film density, and a film thickness of the inorganic film 84 as a gas barrier film are specified. Moreover, attention is paid to the mixed layer in the interface between the organic film 82 and the inorganic film 84, and the thickness of the mixed layer 86 is specified. Accordingly, the present invention has realized a gas barrier film which is excellent not only in gas barrier properties and transparency but also in flexibility and durability.

As described above, the inorganic film 84 of the gas barrier film of the present invention is a film which contains silicon nitride as a main component and in which a compositional ratio of N/Si is 1 to 1.35.

If the compositional ratio of N/Si is lower than 1, the inorganic film 84 is colored, and this leads to a problem in that the inorganic film 84 exhibiting sufficient transparency cannot be obtained.

Inversely, if the compositional ratio of N/Si exceeds 1.35, durability and flexibility deteriorate, and this leads to problems in that sufficient gas barrier properties cannot be secured over a long period of time, and the inorganic film 84 is easily cracked.

In order to more suitably obtain the aforementioned advantages, the compositional ratio of N/Si is preferably 1.05 to 1.25.

The film density of the inorganic film 84 is 2.1 g/cm³ to 2.4 g/cm³.

If the film density is controlled to be equal to or higher than 2.1 g/cm³, this yields preferable results in that a higher degree of durability can be secured, sufficient gas barrier properties can be secured over a long period of time, and the adhesiveness between the inorganic film 84 and the substrate Z or the base layer can be improved. As the film density increases, flexibility decreases, and the film tends to be easily cracked. Therefore, if the film density is controlled to be equal to or lower than 2.4 g/cm³, this yields preferable results in that cracking resulting from the high film density and the deterioration of flexibility can be suitably prevented, and the adhesiveness between the inorganic film 84 and the substrate Z or the base layer can be improved.

In order to more suitably obtain the aforementioned advantages, the film density of the inorganic film 84 is more preferably controlled to be 2.2 g/cm³ to 2.35 g/cm³.

The thickness of the inorganic film 84 is 10 nm to 60 nm.

If the thickness of the inorganic film 84 is controlled to be equal to or greater than 10 nm, sufficient gas barrier properties can be stably secured. Basically, the thicker the inorganic film 84, the better the gas barrier properties. However, if the thickness exceeds 60 nm, flexibility deteriorates, and the film is easily cracked. Accordingly, if the thickness of the inorganic film 84 is controlled to be equal to or smaller than 60 nm, flexibility of the inorganic film 84 can be secured, and cracking and the like can be suitably prevented.

In order to more suitably obtain the aforementioned advantages, the thickness of the inorganic film 84 is more preferably 15 nm to 50 nm.

In the gas barrier film of the present invention, the mixed layer 86 having a thickness of 5 nm to 40 nm is formed in the interface between the organic film 82 and the inorganic film 84.

Since the mixed layer 86, in which the components of the organic film 82 and the inorganic film 84 have been mixed with each other, is formed between the organic film 82 and the inorganic film 84, there is no clear interface between the organic film 82 and the inorganic film 84. Consequentially, the organic film 82 and the inorganic film 84 are chemically bound together through the mixed layer 86, whereby strong adhesiveness can be obtained.

The organic film 82 formed of an organic compound and the inorganic film 84 containing silicon nitride as a main component are different from each other in terms of the composition. Accordingly, a degree of adhesiveness between these films is low, and due to the difference in density thereof, the films exhibit difference in flexibility. Therefore, if the thickness of the mixed layer 86 between the organic film 82 and the inorganic film 84 is smaller than 5 nm, the adhesiveness cannot be sufficiently improved, and it is impossible to secure flexibility by absorbing the difference in density between the organic film 82 and the inorganic film 84. If the mixed layer 86 having a thickness of equal to or greater than 5 nm is formed, the adhesiveness between the organic film 82 and the inorganic film 84 can be improved, and it is also possible to secure flexibility by absorbing the difference in density between the organic film 82 and the inorganic film 84.

If the thickness of the mixed layer 86 exceeds 40 nm, a film formation rate decreases, and a production efficiency of a gas barrier film is reduced. Therefore, if the thickness is controlled to be equal to or smaller than 40 nm, it is possible to manufacture a preferable gas barrier film without reducing the production efficiency.

In order to more suitably obtain the aforementioned advantages, the thickness of the mixed layer 86 is more preferably 10 nm to 30 nm.

As described above, the mixed layer 86 is a layer containing the component derived from the organic film 82 and the component derived from the inorganic film 84. Since the inorganic film 84 contains silicon nitride as a main component, the component derived from the inorganic film 84 is silicon or the like. The component derived from the organic film 82 is carbon or the like.

Accordingly, the film thickness of each of the inorganic film 84 and the mixed layer 86 can be measured by a method in which elementary analysis is performed by XPS (X-ray Photoelectron Spectroscopy) while the gas barrier film 80 is being etched from the surface of the inorganic film 84 side so as to observe the existence of silicon and carbon. Alternatively, the film thickness of each of the inorganic film 84 and the mixed layer 86 can be measured by a method in which the cross-section of the gas barrier film 80 is taken along the thickness direction thereof, and the cross-section is observed with an electron microscope.

In the gas barrier film 80 of the present invention shown in FIG. 1, a single layer of organic film 82 and a single layer of inorganic film 84 are placed on the base material Z₀, but the present invention is not limited to this constitution. For example, similarly to the constitution of a gas barrier film 90 schematically shown in FIG. 2, in which a mixed layer 86a and an inorganic film 84a are formed on a substrate Z consisting of a base material Z₀ and an organic film 82a formed on the base material Z₀, an organic film 82b is formed thereon, and then a mixed layer 86b and an inorganic film 84b are formed thereon, in the gas barrier film of the present invention, a plurality of organic films 82, mixed layers 86, and inorganic films 84 may be alternately laminated on one another to form a constitution in which two or more combinations of the organic film 82, the inorganic film 84, and the mixed layer 86 are laminated on one another.

If a plurality of organic films 82, mixed layers 86, and inorganic films 84 are alternately laminated on one another as described above, this yields a more preferable result in terms of gas barrier properties.

Furthermore, in the present invention, it is preferable for the number of both the organic film 82 and the inorganic film 84 to be plural, but either the organic film 82 or the inorganic film 84 may be present in the form of a plurality of layers, and when both of the films are present in the form of a plurality of layers, the number of the organic film 82 may not be the same as the number of the inorganic film 84.

In addition, in the present invention, in view of surface protection, the organic film 82 may be used as an uppermost layer. Particularly, when the gas barrier film has a plurality of organic films 82, it is preferable to use the organic film 82 as an uppermost layer.

If such a constitution having a plurality of organic films 82 and inorganic films 84 is adopted, it is possible to obtain a gas barrier film which is superior in gas barrier properties, durability, flexibility, mechanical strength, long-term maintainability of gas barrier properties, light extraction efficiency, and the like.

Herein, when the gas barrier film of the present invention has a plurality of inorganic films, at least one of the inorganic films may be the inorganic film 84 forming the mixed layer 86 in the interface between the inorganic film 84 and the organic film 82 as the base thereof. That is, the gas barrier film may have a silicon oxide film or an aluminum oxide film as the inorganic film, in addition to the inorganic film 84 containing silicon nitride as a main component.

However, when the gas barrier film of the present invention has a plurality of inorganic films, all of the inorganic layers are preferably the inorganic film 84 forming the mixed layer 86 in the interface between the inorganic film 84 and the organic film 82 as the base thereof.

Next, a manufacturing method of the gas barrier film 80 of the present invention will be described.

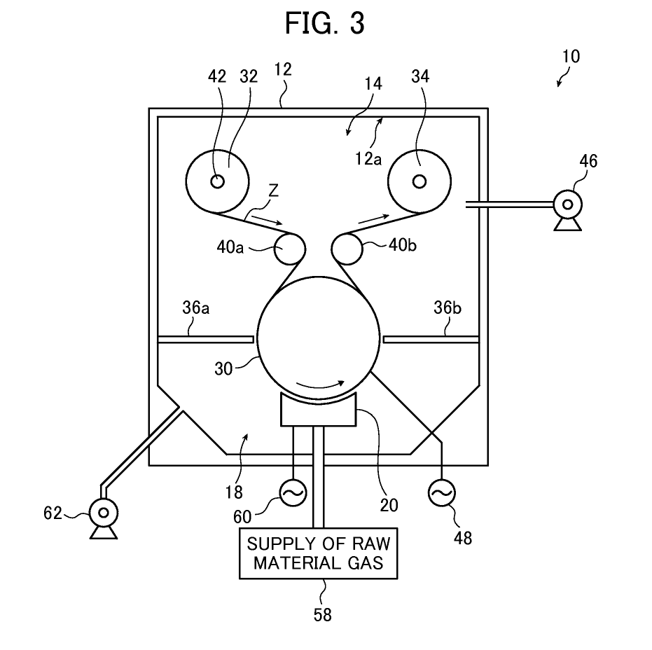

FIG. 3 schematically shows an example of a film-forming apparatus performing the manufacturing method of the present invention. A film-forming apparatus 10 shown in FIG. 3 is basically the same as a known Roll to Roll film-forming apparatus using plasma CVD, except for the film formation conditions.

In the film-forming apparatus 10 illustrated in the drawing, while a long substrate Z (original film) is being transported in a longitudinal direction, a film exhibiting an intended function is formed (manufactured) on the surface of the substrate Z by plasma CVD, whereby a functional film is manufactured.

That is, the film-forming apparatus 10 is an apparatus forming a film by a so-called Roll to Roll process in which the substrate Z is wound off from a substrate roll 32 formed by winding the long substrate Z in a roll shape, a functional film is formed while the substrate Z is being transported in a longitudinal direction, and the substrate Z (that is, the functional film) on which the functional film has been formed is wound up in a roll shape.

The substrate Z is obtained by forming the organic film 82 on the base material Z₀.

The film-forming apparatus 10 shown in FIG. 3 is an apparatus that can form a film on the substrate Z by CCP (Capacitively-Coupled Plasma)-CVD. The film-forming apparatus 10 is constituted with a vacuum chamber 12 and a winding-off chamber 14, a film formation chamber 18, and a drum 30 which are formed inside the vacuum chamber 12.

In the film-forming apparatus 10, the long substrate Z is supplied from the substrate roll 32 of the winding-off chamber 14, and while the substrate Z is being transported in a longitudinal direction in a state of being wound around the drum 30, a film is formed in the film formation chamber 18. Thereafter, the substrate Z is wound up again around a winding-up axle 34 (wound up in a roll shape) in the winding-off chamber 14.

The drum 30 is a cylindrical member that rotates around the centerline thereof in a counterclockwise direction of the drawing.

The drum 30 allows the substrate Z, which has been guided along a predetermined path by a guide roller 40a of the winding-off chamber 14 that will be described later, to be hung around a predetermined area of the circumferential surface thereof, transports the substrate Z in a longitudinal direction while holding the substrate Z in a predetermined position such that the substrate Z is transported into the film formation chamber 18, and sends the substrate Z to a guide roller 40b of the winding-off chamber 14.

Herein, the drum 30 also functions as a counter electrode of a shower electrode 20 of the film formation chamber 18 that will be described later (that is, a pair of electrodes is constituted with the drum 30 and the shower electrode 20).

Moreover, the drum 30 has been connected to a bias supply 48.

The bias supply 48 is a power source supplying bias power to the drum 30.

The bias supply 48 is basically a known bias supply used in various plasma CVD apparatuses.

Herein, in the manufacturing method of the gas barrier film of the present invention, the frequency of the bias power supplied to the drum 30 from the bias supply 48 is lower than the frequency of plasma excitation power and is 0.1 MHz to 1 MHz. Moreover, the bias power supplied to the drum 30 from the bias supply 48 is power 0.02 to 0.5 times stronger than the plasma excitation power supplied to the shower electrode 20 from a high-frequency power source 60 which will be described later.

This point will be specifically described later.

The winding-off chamber 14 is constituted with an inner wall surface 12a of the vacuum chamber 12, the circumferential surface of the drum 30, and partitions 36a and 36b that extend from the inner wall surface 12a to the vicinity of the circumferential surface of the drum 30.

Herein, the tip of the partitions 36a and 36b (the tip in a position opposite to the inner wall surface of the vacuum chamber 12) approaches the circumferential surface of the drum 30 to the position in which the partitions can avoid coming into contact with the substrate Z to be transported, and separates the winding-off chamber 14 from the film formation chamber 18 in a substantially airtight manner.

The winding-off chamber 14 has the aforementioned winding-up axle 34, the guide rollers 40a and 40b, a rotation axle 42, and vacuum exhaust means 46.

The guide rollers 40a and 40b are general guide rollers that guide the substrate Z along a predetermined transport path. Moreover, the winding-up axle 34 is a known winding-up axle for long substance around which the substrate Z having undergone film formation is wound.

In the example illustrated in the drawing, the substrate roll 32, which is the long substrate Z having been wound up in a roll shape, is mounted on the rotation axle 42. When the substrate roll 32 is mounted on the rotation axle 42, the substrate Z is transported along (inserted into) a predetermined path in which the substrate Z passes through the guide roller 40a, the drum 30, and the guide roller 40b and reaches the winding-up axle 34.

In the film-forming apparatus 10, the winding-off of the substrate Z from the substrate roll 32 is performed in synchronization with the winding-up of the substrate Z having undergone the film formation around the winding-up axle 34, and while the long substrate Z is being transported along a predetermined transport path in a longitudinal direction, a film is formed thereon in the film formation chamber 18.

The vacuum exhaust means 46 is a vacuum pump for reducing pressure such that a predetermined degree of vacuum is established inside the winding-off chamber 14. The vacuum exhaust means 46 regulates the internal pressure (a degree of vacuum) of the winding-off chamber 14 such that the pressure (film formation pressure) of the film formation chamber 18 is not influenced.

In the transport direction of the substrate Z, the film formation chamber 18 is disposed in the downstream of the winding-off chamber 14.

The film formation chamber 18 is constituted with the inner wall surface 12a, the circumferential surface of the drum 30, and partitions 36a and 36b that extend from the inner wall surface 12a to the vicinity of the circumferential surface of the drum 30.

In the film-forming apparatus 10, the film formation chamber 18 is a chamber for forming a film on the surface of the substrate Z by CCP (Capacitively-Coupled Plasma)-CVD, and has the shower electrode 20, raw material gas supply means 58, the high-frequency power source 60, and vacuum exhaust means 62.

The shower electrode 20 constitutes a pair of electrodes together with the drum 30 when a film is formed by CCP-CVD in the film-forming apparatus 10. In the example illustrated in the drawing, the shower electrode 20 has the shape approximate to a hollow rectangular parallelepiped for an example and is disposed such that the discharge surface thereof, which is the largest surface thereof, faces the circumferential surface of the drum 30. A plurality of through holes is formed all over the discharge surface facing the drum 30. The shower electrode 20 generates plasma for film formation between the discharge surface thereof and the circumferential surface of the drum 30 with which the shower electrode 20 constitutes the pair of electrodes, and forms a film formation area therebetween.

The raw material gas supply means 58 is known gas supply means used for vacuum film-forming apparatuses such as a plasma CVD apparatus, and supplies raw material gas into the shower electrode 20.

As described above, the surface of the shower electrode 20 that faces the drum 30 has a plurality of through holes. Accordingly, the raw material gas having been supplied to the shower electrode 20 is introduced into a space between the shower electrode 20 and the drum 30 through the through holes.

The high-frequency power source 60 is a power source supplying plasma excitation power to the shower electrode 20. As the high-frequency power source 60, all of the known high-frequency power sources which have been utilized in various plasma CVD apparatuses can be used.

Moreover, the vacuum exhaust means 62 is means for maintaining film formation pressure at a predetermined level by exhausting the film formation chamber 18 such that a gas barrier film is formed by plasma CVD. The vacuum exhaust means 62 is known vacuum exhaust means used for vacuum film-forming apparatuses.

Herein, in the manufacturing method of the gas barrier film of the present invention, for forming a film, the high-frequency power source 60 supplies plasma excitation power with a high frequency of 10 MHz to 100 MHz to the shower electrode. 20 as one of the pair of electrodes, and the bias supply 48 supplies bias power 0.02 to 0.5 times stronger than the plasma excitation power to the drum 30, which constitutes the pair of electrodes together with the shower electrode 20, at a low frequency of 0.1 MHz to 1 MHz.

In the process of forming an inorganic film, which contains silicon nitride as a main component, on the substrate Z by CCP-CVD, if bias power 0.02 to 0.5 times stronger than the plasma excitation power is supplied to the drum 30, which constitutes the pair of electrodes with the shower electrode 20, at a low frequency of 0.1 MHz to 1 MHz, the raw material gas having been ionized by the plasma excitation power is attracted to the substrate Z side and introduced into the organic film 82. Consequentially, it is possible to form the mixed layer 86 having a certain thickness, that is, a thickness of 5 nm to 40 nm.

If the bias power is less than 0.02 times as strong as the plasma excitation power, a mixed layer having a sufficient thickness may not be obtained, and flexibility may deteriorate. Moreover, the film density of the inorganic film may deteriorate, and sufficient gas barrier properties may not be obtained.

If the bias power is more than 0.5 times as strong as the plasma excitation power, the film density of the inorganic film may become too high, and the flexibility may deteriorate. Moreover, the thickness of the mixed layer to be formed may become too great, and it may take a longer time until an inorganic film having a sufficient thickness is formed, hence the film formation rate may decrease.

Accordingly, the bias power is preferably controlled to be 0.02 to 0.5 times stronger than the plasma excitation power.

The raw material gas supplied from the raw material gas supply means 58 is gas containing, as reactant gas, at least silane gas and ammonia gas. A flow ratio between the silane gas and the ammonia gas preferably satisfies SiH₄:NH₃=1:1.2 to 1:3.0.

If the flow ratio between the silane gas and the ammonia gas is within the above range, the compositional ratio of N/Si in the inorganic film 84 to be formed can be controlled to be 1 to 1.35, and the film density thereof can be controlled to be 2.1 g/cm³ to 2.4 g/cm³.

If the ratio of a flow rate of the ammonia gas to a flow rate of the silane gas is too high, the compositional ratio of N/Si in the inorganic film becomes high, and the film density thereof becomes too high. Accordingly, durability and flexibility may deteriorate. In contrast, if the ratio of the flow rate of the ammonia gas to the flow rate of the silane gas is too low, the compositional ratio of N/Si becomes too low, hence a visible light transmittance may deteriorate.

Therefore, the flow ratio between the silane gas and the ammonia gas is preferably controlled to be SiH₄:NH₃=1:1.2 to 1:3.0.

Moreover, if necessary, as the raw material gas, in addition to the reactant gas, various gases like inert gases such as helium gas, neon gas, argon gas, krypton gas, xenon gas, and radon gas, hydrogen gas, and the like may be concurrently used.

The film formation pressure in the film formation chamber 18 is preferably controlled to be 10 Pa to 80 Pa. If the film formation pressure is lower than 10 Pa, it is difficult to increase the film formation rate. If the film formation pressure exceeds 80 Pa, the raw material gas may react in the atmosphere, and micropowder may be generated. Consequentially, the quality of the film to be formed on the substrate Z deteriorates.

In the present example, as a preferable embodiment, a constitution which is a so-called Roll to Roll process, in which film formation is performed by winding a long substrate around a drum while the substrate is being transported in a longitudinal direction thereof, is adopted, but the present invention is not limited thereto. For example, a Roll to Roll apparatus having a constitution, in which a pair of plate-shaped electrodes facing each other is disposed in a film formation chamber, and while a long substrate is transported in a longitudinal direction thereof between the pair of electrodes, raw material gas is supplied to a space between the substrate and the electrode to perform film formation by plasma CVD, may be adopted.

Up to now, the gas barrier film and the manufacturing method of the gas barrier film of the present invention have been described in detail, but the present invention is not limited to the above examples. Needless to say, the present invention may be improved or modified in various ways within a scope that does not depart from the gist of the present invention.

### EXAMPLES

### Example 1

By using the film-forming apparatus 10 that performs film formation by a CCP-CVD method, the inorganic film 84 (gas barrier film) as a silicon nitride film was formed on the substrate Z by the manufacturing method of the present invention.

As the substrate Z, a substrate in which the organic film 82 containing acrylate as a main component had been formed on the surface of a PET film (A4300 manufactured by TOYOBO CO., LTD.) having a thickness of 100 μm was used. A visible light transmittance of the substrate Z was 91%.

As raw material gas, silane gas (SiH₄), ammonia gas (NH₃), and hydrogen gas (H₂) were used. The flow rates of the silane gas, the ammonia gas, and the hydrogen gas were controlled to be 100 scan, 200 scan, and 1,000 scan respectively. That is, a flow ratio between the silane gas and the ammonia gas was controlled to be 1:2.

As the high-frequency power source 60, a high-frequency power source with a frequency of 13.56 MHz was used, and power of 2 kW was supplied to the shower electrode 20.

As the bias supply 48, a high-frequency power source with a frequency of 0.4 MHz was used, and power of 0.2 kW (0.1 times stronger than plasma excitation power) was supplied to the drum 30.

The vacuum chamber was exhausted such that the internal pressure of the vacuum chamber became 50 Pa.

The transport speed of the substrate Z was controlled to be 1.0 m/min.

Under the aforementioned conditions, a functional film having a length of 10 m was formed on the substrate Z in the film-forming apparatus 10. Thereafter, the thickness of the inorganic film 84 in the obtained gas barrier film 80 was measured using a step profiler (Dektak manufactured by ULVAC Technologies, Inc.). The thickness of the inorganic film 84 was 41.5 nm. The film density of the inorganic film 84 was measured using a thin-film X-ray diffractometer (ATX-E manufactured by Rigaku Corporation) by XRR (X-Ray Reflectometry). The film density was 2.23 g/cm³. The amount of nitrogen and silicon distributed in the inorganic film 84 was measured using an X-ray photoelectron spectrometer (ESCA-3400 manufactured by Shimadzu Corporation) by XPS (X-ray Photoelectron Spectroscopy). The compositional ratio N/Si in the film was 1.15.

In addition, the thickness of the mixed layer 86 was measured by a method in which while the gas barrier film 80 was being etched from the surface of the inorganic film 84 side, elementary analysis was performed by XPS (X-ray Photoelectron Spectroscopy) by using an X-ray photoelectron spectrometer (ESCA-3400 manufactured by Shimadzu Corporation) so as to observe the existence of silicon and carbon. As a result, the thickness of the mixed layer 86 was confirmed to be 15 nm.

Moreover, the visible light transmittance of the gas barrier film 80 was measured as the average transmittance (including the substrate) at a wavelength of 400 nm to 800 nm by using a spectrophotometer (U-4000 manufactured by Hitachi High-Technologies Corporation). The visible light transmittance was 87.1%.

Furthermore, under each of the conditions of (1) the point in time immediately after the preparation of the gas barrier film 80 (0 hr), (2) the point in time after the gas barrier film 80 was left in an environment of a temperature of 85° C. and a relative humidity of 85% for 1,000 hours (1,000 hr), and (3) the point in time after the operation of winding the gas barrier film 80 around a cylindrical rod of φ 6 mm and then unfolding the film was performed 100 times (bending), a water vapor transmittance [g/(m²·day)] of the gas barrier film 80 was measured by a calcium corrosion method (method described in JP 2005-283561 A). As a result, it was confirmed that the water vapor transmittance was (1) 2.5×10⁻⁵ [g/(m²·day)] immediately after the preparation of the film, (2) 3.1×10⁻⁵ [g/(m²·day)] after the film was left for 1,000 hours, and (3) 2.8×10⁻⁵ [g/(m²·day)] after the bending.

### Example 2

The gas barrier film 80 was prepared in the same manner as in Example 1, except that the bias power supplied to the drum 30 was controlled to be 0.4 kW (0.2 times stronger than plasma excitation power). Thereafter, the film thickness, the film density, and the compositional ratio of the inorganic film 84 and the film thickness of the mixed layer 86 were measured. As a result, it was confirmed that the film thickness of the inorganic film 84 was 42.3 nm, the film density thereof was 2.31 g/cm³, and the compositional ratio N/Si thereof was 1.20. The film thickness of the mixed layer 86 was 21 nm. Accordingly, it was confirmed that these results satisfied the scope of the present invention.

Moreover, the visible light transmittance and the water vapor transmittance of the gas barrier film 80 were measured. The visible light transmittance was 87.5%. The water vapor transmittance was (1) 1.9×10⁻⁵ [g/(m²·day)] immediately after the preparation of the film, (2) 2.2×10⁻⁵ [g/(m²·day)] after the film was left for 1,000 hours, and (3) 2.4×10⁻⁵ [g/(m²·day)] after the bending.

### Example 3

On the surface of the gas barrier film 80 prepared in the same manner as in Example 1, the organic film 82b containing acrylate as a main component was formed. Thereafter, by using the resultant film as a substrate, the inorganic film 84b was formed thereon in the same manner as in Example 1, thereby preparing the gas barrier film 90 on which the organic film 82 and the inorganic film 84 had been laminated on each other as shown in FIG. 2. Subsequently, the film thickness, the film density, and the compositional ratio of the inorganic films 84a and 84b and the film thickness of the mixed layers 86a and 86b were measured. As a result, it was confirmed that the film thickness of the inorganic film 84a was 40.6 nm, the film density thereof was 2.24 g/cm³, and the compositional ratio N/Si thereof was 1.16, and it was confirmed that the film thickness of the inorganic film 84b was 38.9 nm, the film density thereof was 2.21 g/cm³, and the compositional ratio N/Si thereof was 1.12. The film thickness of the mixed layer 86a was 14 nm, and the film thickness of the mixed layer 86b was 17 nm. That is, these results satisfied the scope of the present invention.

Moreover, the visible light transmittance and the water vapor transmittance of the gas barrier film 90 were measured. As a result, the visible light transmittance was 86.6%. The water vapor transmittance was (1) equal to or lower than 1.0×10⁻⁵ [g/(m² day)] immediately after the preparation of the film, (2) equal to or lower than 1.0×10⁻⁵ [g/(m²·day)] after the film was left for 1,000 hours, and (3) equal to or lower than 1.0×10⁻⁵ [g/(m²·day)] after the bending.

### Comparative Example 1

A gas barrier film was prepared in the same manner as in Example 1, except that the bias power was not supplied (0 kW) to the drum 30. Thereafter, the film thickness, the film density, and the compositional ratio of the inorganic film and the film thickness of the mixed layer were measured. As a result, it was confirmed that the film thickness of the inorganic film was 40.1 nm, the film density thereof was 2.02 g/cm³, and the compositional ratio N/Si thereof was 1.05. The film thickness of the mixed layer 86 was 3 nm. That is, these results did not satisfy the scope of the present invention.

The visible light transmittance and the water vapor transmittance of the gas barrier film were measured. As a result, the visible light transmittance was 85.5%. The water vapor transmittance was (1) 4.7×10⁻⁴ [g/(m²·day)] immediately after the preparation of the film, (2) 8.0×10⁻³ [g/(m²·day)] after the film was left for 1,000 hours, and (3) 3.6×10⁻³ [g/(m²·day)] after the bending.

### Comparative Example 2

A gas barrier film was prepared in the same manner as in Example 1, except that the flow rate of the ammonia gas was controlled to be 320 sccm, and the flow ratio between the silane gas and the ammonia gas was controlled to be 1:3.2. Thereafter, the film thickness, the film density, and the compositional ratio of the inorganic film and the film thickness of the mixed layer were measured. As a result, it was confirmed that the film thickness of the inorganic film was 38.6 nm, the film density thereof was 2.27 g/cm³, and the compositional ratio N/Si thereof was 1.37. The film thickness of the mixed layer 86 was 17 nm. That is, these results did not satisfy the scope of the present invention.

The visible light transmittance and the water vapor transmittance of the gas barrier film were measured. As a result, the visible light transmittance was 89.2%. The water vapor transmittance was (1) 4.8×10⁻⁵ [g/(m²·day)] immediately after the preparation of the film, (2) 1.5×10⁻⁴ [g/(m²·day)] after the film was left for 1,000 hours, and (3) 2.3×10⁻³ [g/(m²·day)] after the bending.

### Comparative Example 3

A gas barrier film was prepared in the same manner as in Example 1, except that the flow rate of the ammonia gas was controlled to be 100 sccm, and the flow ratio between the silane gas and the ammonia gas was controlled to be 1:1. Thereafter, the film thickness, the film density, and the compositional ratio of the inorganic film and the film thickness of the mixed layer were measured. As a result, it was confirmed that the film thickness of the inorganic film was 39.5 nm, the film density thereof was 2.18 g/cm³, and the compositional ratio N/Si thereof was 0.97. The film thickness of the mixed layer 86 was 12 nm. That is, these results did not satisfy the scope of the present invention.

The visible light transmittance and the water vapor transmittance of the gas barrier film were measured. As a result, the visible light transmittance was 83.8%. The water vapor transmittance was (1) 3.9×10⁻⁵ [g/(m²·day)] immediately after the preparation the film, (2) 4.6×10⁻⁵ [g/(m²·day)] after the film was left for 1,000 hours, and (3) 4.4×10⁻⁵ [g/(m²·day)] after the bending.

### Comparative Example 4

A gas barrier film was prepared in the same manner as in Example 1, except that the transport speed was controlled to be 0.7 m/min. Thereafter, the film thickness, the film density, and the compositional ratio of the inorganic film and the film thickness of the mixed layer were measured. As a result, it was confirmed that the film thickness of the inorganic film was 68.7 nm, the film density thereof was 2.25 g/cm³, and the compositional ratio N/Si thereof was 1.14. The film thickness of the mixed layer 86 was 17 nm. That is, these results did not satisfy the scope of the present invention.

The visible light transmittance and the water vapor transmittance of the gas barrier film were measured. As a result, the visible light transmittance was 86.0%. The water vapor transmittance was (1) 1.6×10⁻⁵ [g/(m²·day)] immediately after the preparation of the film, (2) 2.0×10⁻⁵ [g/(m²·day)] after the film was left for 1,000 hours, and (3) 4.7×10⁻³ [g/(m²·day)] after the bending.

### Comparative Example 5

A gas barrier film was prepared in the same manner as in Example 1, except that the bias power supplied to the drum was controlled to be 1.1 kW (0.55 times stronger than plasma excitation power). Thereafter, the film thickness, the film density, and the compositional ratio of the inorganic film and the film thickness of the mixed layer were measured. As a result, it was confirmed that the film thickness of the inorganic film was 32.1 nm, the film density thereof was 2.44 g/cm³, and the compositional ratio N/Si thereof was 1.27. The film thickness of the mixed layer 86 was 43 nm. That is, these results did not satisfy the scope of the present invention.

The visible light transmittance and the water vapor transmittance of the gas barrier film were measured. As a result, the visible light transmittance was 88.1%. The water vapor transmittance was (1) 2.3×10⁻⁵ [g/(m²·day)] immediately after the preparation of the film, (2) 3.5×10⁻⁵ [g/(m²·day)] after the film was left for 1,000 hours, and (3) 7.1×10⁻⁴ [g/(m²·day)] after the bending.

The measured results are shown in Table 1.

TABLE 1

| | | Inorganic layer | | | Thickness | | water vapor transmittance | | |
|---|---|---|---|---|---|---|---|---|---|
| | | Film | Film | Film | of mixed | Visible light | | (2) | (3) After |
| | | thickness | density | composition | layer | transmittance | (1) 0 h | 1000 h | bending |
| | | nm | g/cm³ | N/Si | nm | % | 10⁻⁵ g/(m² · day) | | |
| Example 1 | | 41.5 | 2.23 | 1.15 | 15 | 87.1 | 2.5 | 3.1 | 2.8 |
| Example 2 | | 42.3 | 2.31 | 1.2 | 21 | 87.5 | 1.9 | 2.2 | 2.4 |
| Example 3 | Substrate | 40.6 | 2.24 | 1.16 | 14 | 86.6 | Equal | Equal | Equal |
| | side | | | | | | to or | to or | to or |
| | | | | | | | lower | lower | lower |
| | | | | | | | than 1 | than 1 | than 1 |
| | Surface | 38.9 | 2.21 | 1.12 | 17 | | | | |
| | side | | | | | | | | |

| | | | | | | | | |
|---|---|---|---|---|---|---|---|---|
| Comparative example 1 | 40.1 | 2.02 | 1.05 | 3 | 85.5 | 47 | 800 | 360 |
| Comparative example 2 | 38.6 | 2.27 | 1.37 | 17 | 89.2 | 4.8 | 15 | 230 |
| Comparative example 3 | 39.5 | 2.18 | 0.97 | 12 | 83.8 | 3.9 | 4.6 | 4.4 |
| Comparative example 4 | 68.7 | 2.25 | 1.14 | 17 | 86 | 1.6 | 2 | 470 |
| Comparative example 5 | 32.1 | 2.44 | 1.27 | 43 | 88.1 | 2.3 | 3.5 | 71 |

From Table 1, it is understood that Examples 1 to 3 as examples of the present invention exhibit excellent gas barrier properties and a high degree of light transmission properties. Moreover, from the fact that the gas barrier properties do not deteriorate even after the gas barrier films are left as they are for 1,000 hours, it is understood that the films exhibit a high degree of durability. Furthermore, from the fact that the gas barrier properties do not deteriorate even after the gas barrier films are repeatedly bent, it is understood that the films exhibit a high degree of flexibility.

In contrast, from Comparative example 1, it is understood that the lower the film density is, the further the gas barrier properties deteriorate. It is also understood that as the thickness of the mixed layer decreases, flexibility is reduced, and the gas barrier properties deteriorate after the repetitive bending. Moreover, it is understood that if the bias power at the time of film formation is low, a mixed layer having a sufficient thickness cannot be formed.

In Comparative example 2, the gas barrier properties deteriorated after 1,000 hours and after the repetitive bending. From Comparative example 2, it is understood that when the compositional ratio N/Si is high, the barrier film is oxidized over time and shows a decrease in density thereof, and accordingly, durability thereof deteriorates. It is also understood that flexibility thereof deteriorates. Moreover, it is understood that as the ratio of a flow rate of the ammonia gas to a flow rate of the silane gas at the time of film formation increases, the compositional ratio N/Si becomes too high.

From Comparative example 3, it is understood that the lower the compositional ratio N/Si is, the further the transmittance decreases. It is also understood that as the ratio of a flow rate of the ammonia gas to a flow rate of the silane gas at the time of film formation decreases, the compositional ratio N/Si becomes too low.

From Comparative example 4, it is understood that as the film thickness of the inorganic film increases, the flexibility decreases, and the gas barrier properties deteriorate after the repetitive bending.

From Comparative example 5, it is understood that as the film density of the inorganic film increases, the flexibility deteriorates, and the gas barrier properties deteriorate after the repetitive bending. It is also understood that as the proportion of the bias power increases, the film density of the inorganic film is heightened.

By the above results, the effects of the present invention become evident.

What is claimed is:

1. A gas barrier film comprising:
a substrate of which the surface is formed of an organic material;
an inorganic film which is formed on the substrate and contains silicon nitride; and
a mixed layer which is formed in an interface between the substrate and the inorganic film, and contains components derived from the organic material and the inorganic film,
wherein a compositional ratio N/Si between nitrogen and silicon contained in the inorganic film is 1.00 to 1.35,
the inorganic film has a film density of 2.1 g/cm³ to 2.4 g/cm³ and a film thickness of 10 nm to 60 nm, and
the mixed layer has a thickness of 5 nm to 40 nm.

2. The gas barrier film according to claim 1, further comprising:
an organic film formed on the inorganic film; and
an inorganic film formed on the organic film.

3. The gas barrier film according to claim 1,
wherein the substrate has a layer in which an organic film and an inorganic film are alternately formed.

4. A manufacturing method of the gas barrier film according to claim 1,
wherein while a long substrate of which the surface is formed of an organic material is being transported in a longitudinal direction thereof, by using a film forming unit having a pair of electrodes disposed so as to make the substrate being transported interposed therebetween, an inorganic film containing silicon nitride is formed on the substrate by capacitively-coupled plasma CVD, and
for forming the inorganic film, plasma excitation power with a high frequency of 10 MHz to 100 MHz is supplied to one of the pair of electrodes, and bias power 0.02 to 0.5 times stronger than the plasma excitation power is supplied to the other electrode at a frequency of 0.1 MHz to 1 MHz which is lower than the frequency of the plasma excitation power.

5. The manufacturing method of the gas barrier film according to claim 4,
wherein raw material gas for forming the inorganic film contains silane gas and ammonia gas, and a gas flow ratio between the silane gas and the ammonia gas is SiH₄:NH₃=1:1.2 to 1:3.0.

6. The manufacturing method of the gas barrier film according to claim 4,
wherein a film formation pressure at the time of forming the inorganic film is controlled to be 10 Pa to 80 Pa.
